(19) United States
(12) Patent Application Publication
(10) Pub. No.: US 2015/0008504 A1
(43) Pub. Date: Jan. 8, 2015

(54) NON-VOLATILE MEMORY STRUCTURE AND MANUFACTURING METHOD THEREOF

(71) Applicant: United Microelectronics Corp., Hsin-Chu City (TW)

(72) Inventors: Chun-Lung Chang, Yilan County (TW); Tzu-Ping Chen, Hsinchu County (TW); Chih-Haw Lee, New Taipei City (TW); Kuan-Yi Tseng, Tainan City (TW); Chih-Jung Chen, Hsinchu County (TW); Chien-Hung Chen, Hsin-Chu City (TW)

(21) Appl. No.: 13/935,570

(22) Filed: Jul. 5, 2013

(51) Int. Cl. H01L 29/792; H01L 29/66

(52) U.S. Cl. CPC H01L 29/792; H01L 29/66833
USPC 257/324; 438/287

(57) ABSTRACT

A non-volatile memory structure includes a substrate, a gate electrode formed on the substrate, conductive spacers respectively formed on two sides of the gate electrode, and an oxide-nitride-oxide (ONO) structure having an inverted T shape formed on the substrate. The gate electrode includes a gate conductive layer and a gate dielectric layer. The ONO structure includes a base portion and a body portion. The base portion of the ONO structure is sandwiched between the gate electrode and the substrate, and between the conductive spacer and the substrate. The body portion of the T-shaped ONO structure is upwardly extended from the base portion and sandwiched between the gate electrode and the conductive spacer.

### BACKGROUND OF THE INVENTION

1. Field of the Invention

The present invention relates to a non-volatile memory structure and a manufacturing method thereof, and more particularly, to a silicon-oxide-nitride-oxide-semiconductor (hereinafter abbreviated as SONOS) non-volatile memory structure and a manufacturing method thereof.

2. Description of the Prior Art

Semiconductor memory devices are prevalently used in computer and electronics industries as a means for retaining digital information. Typically, the semiconductor memory devices are divided into volatile and non-volatile memory devices depending on whether the data stored in the memory devices is completely lost or not in case of power interruption. And the non-volatile memory devices, which can retain their data even when the power supply is interrupted, have been widely employed.

In the conventional non-volatile memory technology, a SONOS memory structure is to build a silicon nitride layer sandwiched between two silicon oxide layers for serving as the charge trap layer while the two silicon oxide layers respectively serve as a charge tunnel layer and a charge block layer. This oxide-nitride-oxide (ONO) multilayered structure is further formed between a semiconductor substrate and a silicon gate, and thus a SONOS memory structure is constructed.

Since the microprocessors have become more powerful, requirement to memory devices of large-capacity and low-cost is raised. To satisfy such trend and achieve challenge of high integration in semiconductor devices, memory miniaturization is kept on going, and thus fabrication process of memory structure is getting complicated. With this trend toward miniaturization of integrated circuit and reduction of the feature size, it is more and more important yet difficult to built SONOS structure having larger ONO film length for storing more charges.

### SUMMARY OF THE INVENTION

According to the claimed invention, a non-volatile memory structure is provided. The non-volatile memory structure includes a substrate, a gate electrode formed on the substrate, conductive spacers respectively formed on two sides of the gate electrode, and an oxide-nitride-oxide (ONO) structure having an inverted T shape formed on the substrate. The gate electrode includes a gate conductive layer and a gate dielectric layer. The ONO structure includes a base portion and a body portion. The base portion of the ONO structure is sandwiched between the gate electrode and the substrate, and between the conductive spacer and the substrate. The body portion of the ONO structure is upwardly extended from the base portion and sandwiched between the gate electrode and the conductive spacer.

According to the claimed invention, a non-volatile memory structure is provided. The non-volatile memory structure includes a substrate, a gate conductive layer formed on the substrate, a gate dielectric layer, and an ONO structure. The gate conductive layer includes a first part and second parts formed at two sides of the first part. The gate dielectric layer is formed between the substrate and the first part of the gate conductive layer. The ONO structure includes a base portion and a body portion. The base portion of the ONO structure is formed between the gate conductive layer and the substrate, and the body portion of the ONO structure is formed between the first part and the second part of the gate conductive layer.

According to the claimed invention, a method for manufacturing a non-volatile memory structure is provided. According to the method, substrate having a gate electrode formed thereon is provided. The gate electrode includes a gate conductive layer and a gate dielectric layer. Then, a first etching process is performed to remove a portion of the gate dielectric layer and thus a cavity under the gate conductive layer is formed. After forming the cavity, a first silicon oxide (hereinafter abbreviated as SiO₂) layer covering sidewalls of the cavity and a surface of the substrate is formed and followed by forming a silicon nitride (hereinafter abbreviated as SiN) layer on the substrate. The SiN layer fills in the cavity and covers the gate electrode. Next, a second SiO₂ layer covering the SiN layer is formed and followed by forming a conductive layer covering the second SiO₂ layer. After forming the conductive layer, an etching back process is performed to form a conductive spacer respectively at sidewalls of the gate electrode and to form an ONO structure having an inverted T shape.

According to the non-volatile memory structure and the manufacturing method provided by the present invention, a conductive spacer is respectively formed on sidewalls of the gate electrode and serves as a part of the gate electrode. The conductive spacers are provided to gain a longer ONO film by constructing the ONO structure having the inverted T shape. Consequently, more charges can be stored.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 are schematic drawings illustrating a method for manufacturing a non-volatile memory structure provided by a preferred embodiment of the present invention, wherein

FIG. 2 is a schematic drawing in a step subsequent to FIG. 1,

FIG. 3 is a schematic drawing in a step subsequent to FIG. 2,

FIG. 4 is a schematic drawing in a step subsequent to FIG. 3,

FIG. 5 is a schematic drawing in a step subsequent to FIG. 4,

FIG. 6 is a schematic drawing in a step subsequent to FIG. 5,

FIG. 7 is a schematic drawing in a step subsequent to FIGS. 6, and

FIG. 8 is a schematic drawing in a step subsequent to FIG. 7.

FIG. 9 is a schematic drawing illustrating a modification to the preferred embodiment.

### DETAILED DESCRIPTION

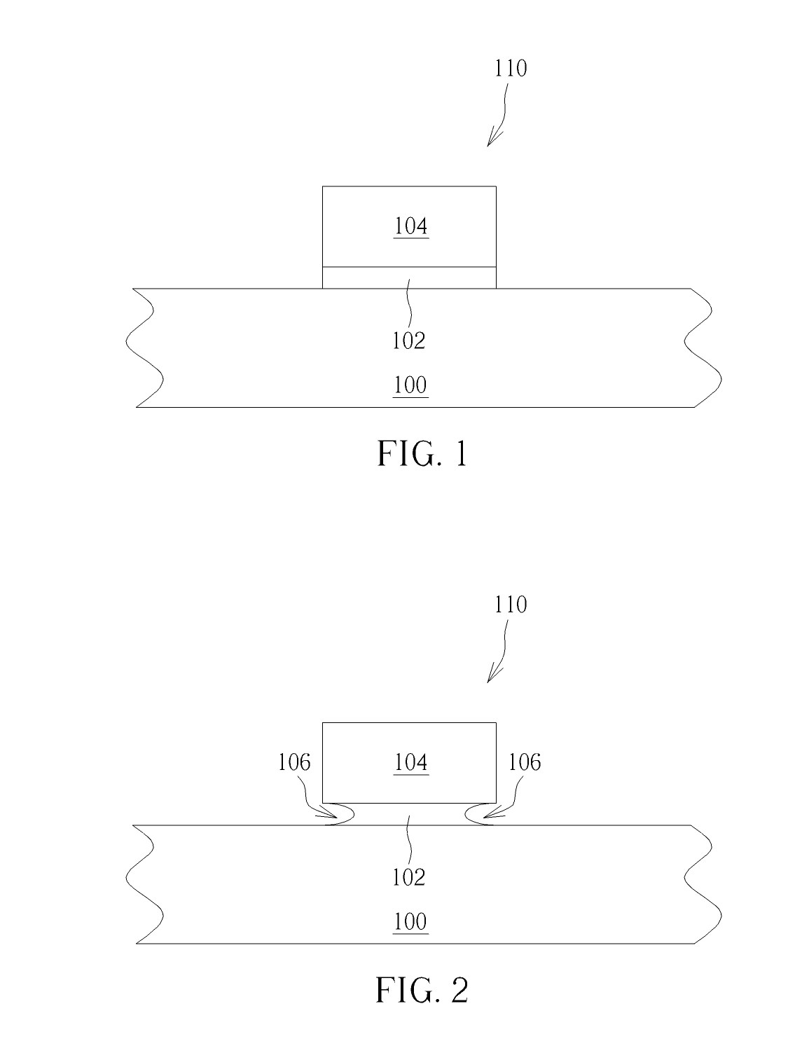

Please refer to FIGS. 1-8, which are drawings illustrating a method for manufacturing a non-volatile memory structure provided by a preferred embodiment of the present invention. As shown in FIG. 1, a substrate 100 is provided. The substrate 100 includes, for example but not limited to, silicon substrate, gallium arsenide (GaAs) substrate, silicon on insulator layer (SOI) substrate, epitaxial substrate, silicon germanium substrate, or any other common semiconductor material substrate. Subsequently, a gate dielectric layer 102 and a gate conductive layer 104 are sequentially formed on the substrate 100 and followed by performing a patterning step. Consequently, a gate electrode 110 is formed on the substrate 100. The gate dielectric layer 102 includes SiO₂ and the gate conductive layer 104 includes polysilicon in accordance with the preferred embodiment.

Please refer to FIG. 2. Next, an etch process is performed. It is noteworthy that an etchant used in the wet etch process includes etching rates substantially different between polysilicon and SiO₂. Therefore, a portion of the gate dielectric layer 102 is removed and a cavity 106 is consequently formed under the gate conductive layer 104. As shown in FIG. 2, a portion of the bottom corner of the gate conductive layer 104 is exposed in each cavity 106. More important, a depth of the cavity 106 is between 200 Angstroms (A) and 300 Å.

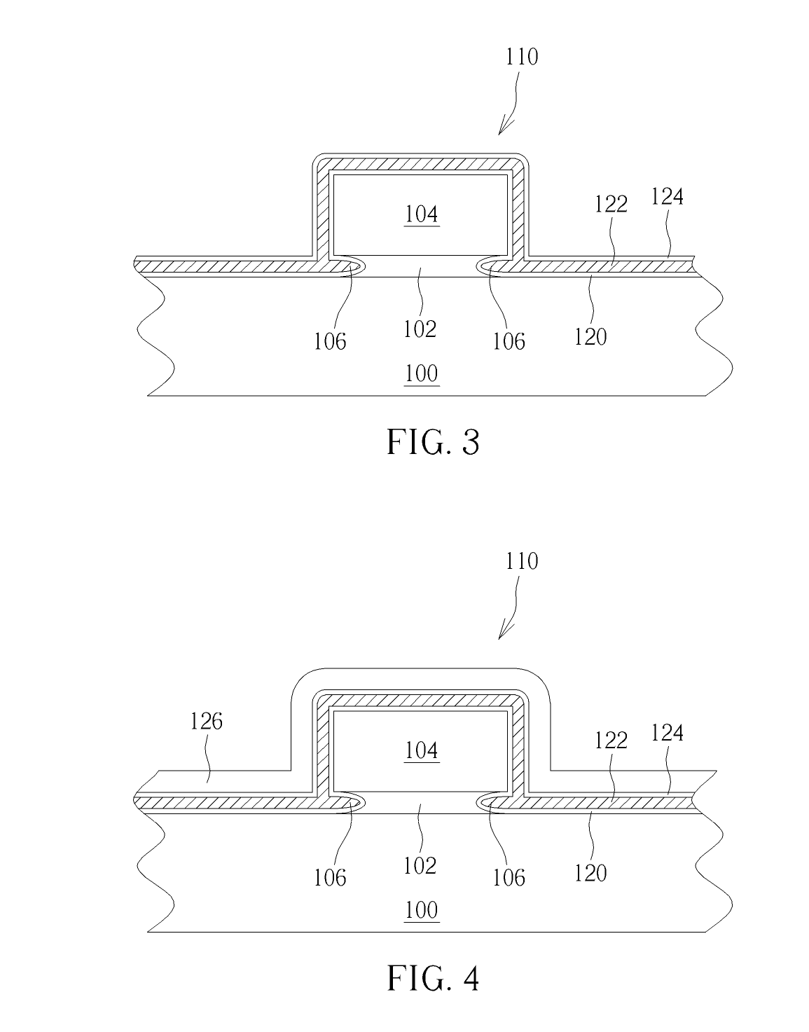

Please refer to FIG. 3. After forming the cavity 106 by the etch process, an oxidation process is performed. The oxidation process can include RTO or be performed in a furnace, but not limited to this. Because the gate conductive layer 104 and the substrate 100 include polysilicon material, it is oxidized during the oxidation process and thus a first SiO₂ layer 120 is grown on a surface of the gate conductive layer 104, sidewalls of the cavity 106, and a surface of the substrate 100. As shown in FIG. 3, the first SiO₂ layer 120 covering the sidewalls of the cavity 106 is also taken as covering the bottom of the gate conductive layer 104 exposed in the cavity 106.

Please still refer to FIG. 3. After forming the first SiO₂ layer 120 by the oxidation process, a SiN layer 122 is formed on the substrate 100 and the gate electrode 110. It is noteworthy that by forming the SiN layer 122, the cavity 106 is filled up with the SiN material as shown in FIG. 3. Then, a second SiO₂ layer 124 is formed to cover the SiN layer 122 on the substrate 100.

Please refer to FIG. 4. After forming the second SiO₂ layer 124, a conductive layer 126 is formed to cover the second SiO₂ layer 124 on the substrate 100. The conductive layer 126 includes a thickness, and the thickness is between 200 Å and 600 Å.

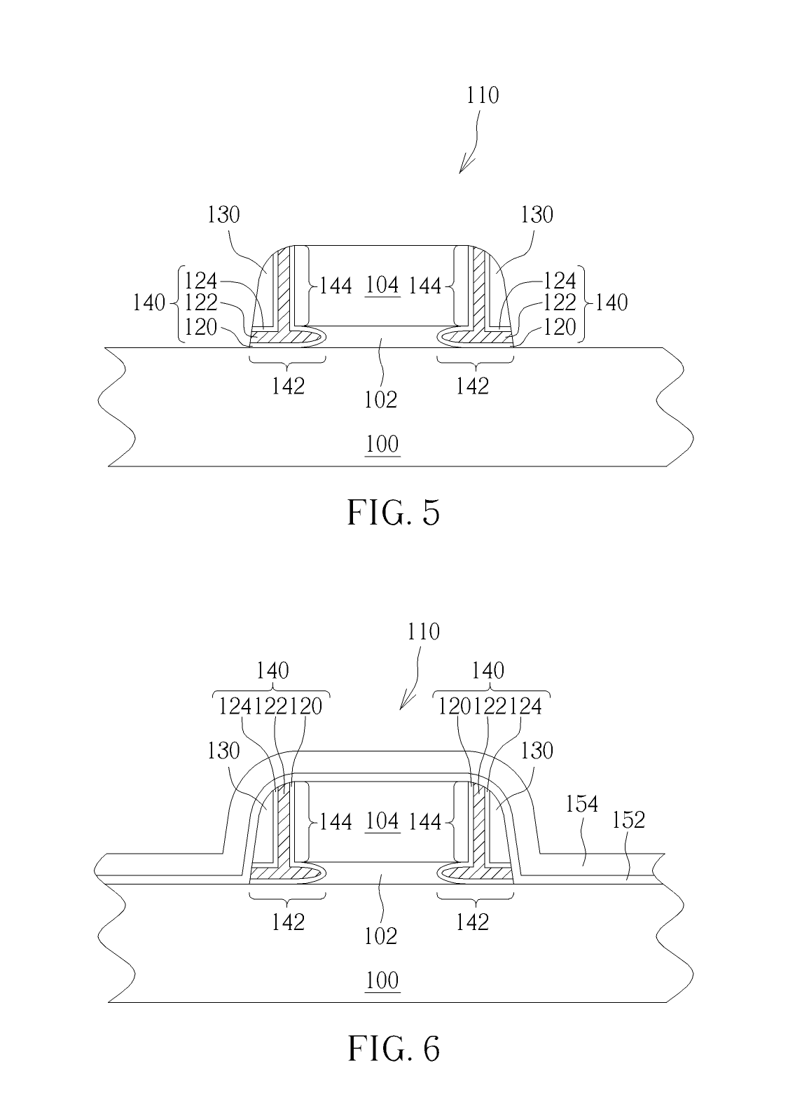

Please refer to FIG. 5. Next, an etching back process is performed remove a portion of the conductive layer 126, a portion of the second SiO₂ layer 124, a portion of the SiN layer 122, and a portion of the first SiO₂ layer 120 from the substrate 100. Consequently, a conductive spacer 130 is respectively formed at sidewalls of the gate electrode 110 and an ONO structure 140 having an inverted T shape is respectively formed at two sides of the gate electrode 110. The conductive spacer 130 includes a thickness that is the same with the thickness of the conductive layer 126. Accordingly, the thickness of the conductive spacer 130 is between 200 Å and 600 Å. As shown in FIG. 5, the T-shaped ONO structure 140 includes a base portion 142 and the body portion 144 upwardly extended from the base portion 142. It is noteworthy that the base portion 142 of the ONO structure 140 is sandwiched between the gate electrode 110 and the substrate 100, and also sandwiched between the conductive spacer 130 and the substrate 100. More important, the body portion 144 of the ONO structure 140 is sandwiched between the gate electrode 110 and the conductive spacer 130. The base portion 142 of the ONO structure 140 comprises a length, which is a sum of the depth of the cavity 106, the thickness of the SiN layer 122, and the thickness of the conductive spacer 130. In the preferred embodiment, the length of the ONO structure 140 is between 400 Å and 700 Å, but not limited to this. In other words, the length of the charge trapping layer of the ONO structure 140 is not only determined by the depth of the cavity 106 and the thickness of the SiN layer 122, but also by the thickness of the conductive spacer 130. Accordingly, the length of the charge trapping layer is increased and thus more charges can be stored.

Please refer to FIG. 6. After forming the conductive spacer 130 and the ONO structure 140, another SiO₂ layer 152 and another SiN layer 154 are sequentially formed on the substrate 100 to cover the conductive spacer 130, the ONO structure 140, and the gate electrode 110. Additionally, the SiN layer 154 can be replaced by a silicon carbide (SiCN) layer, but not limited to this.

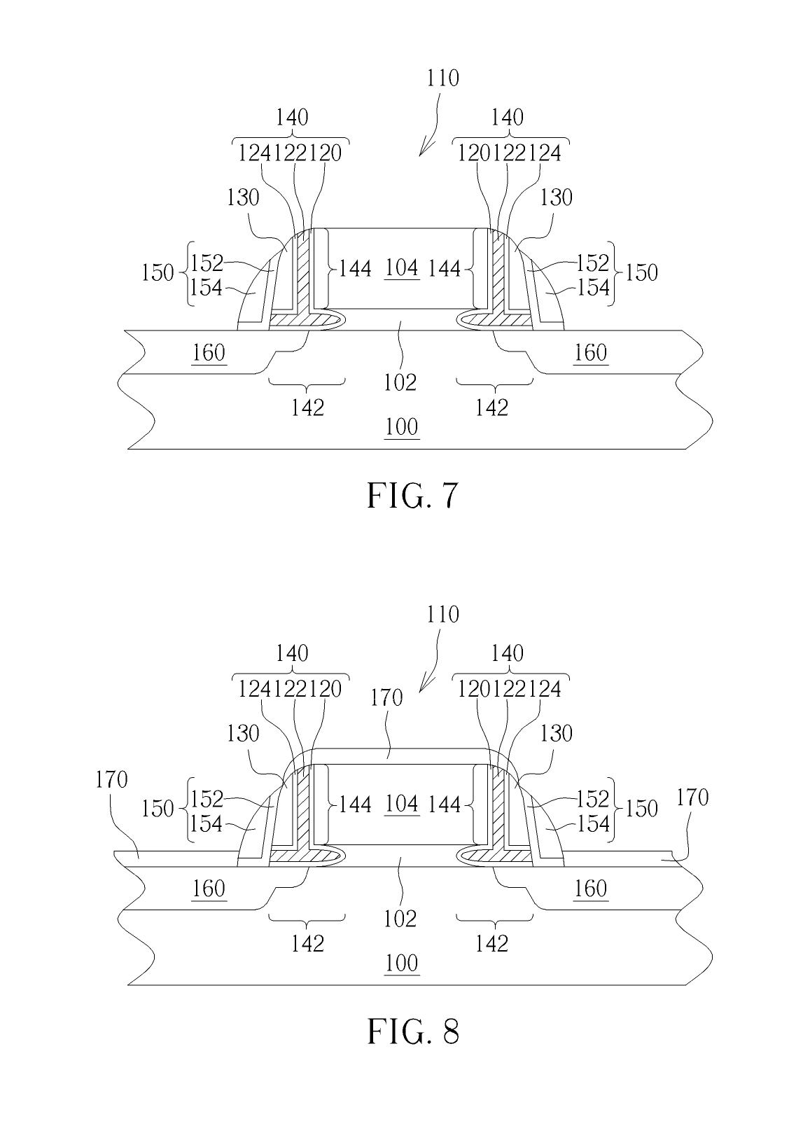

Please refer to FIG. 7. Next, another etching back process is performed to remove a portion of the SiN layer 154 and a portion of the SiO₂ layer 152 to form an insulating spacer 150 respectively at outside of the conductive spacers 130. After forming the insulating spacers 150, ion implantation is performed to form a source/drain 160 in the substrate 100 as shown in FIG. 7. In addition, those skilled in the art would easily realize that ion implantation for forming lightly-doped drains (LDDs) can be performed if required.

Please refer to FIG. 8. After forming the source/drain 160, a salicide process is performed to form a salicide layer 170 on the gate conductive layer 104, the conductive spacer 130, and the source/drain 160. It is noteworthy that the conductive spacers 130 and the gate conductive layer 104 are electrically connected to each other by the salicide layer 170 as shown in FIG. 8. Because the conductive spacers 130 and the gate conductive layer 104 are electrically connected by the salicide layer 170, the conductive spacers 130 obtain a voltage the same with the gate conductive layer 104. Accordingly, the conductive spacers 130 can be taken as a part of the gate conductive layer after forming the salicide layer 170.

In other words, the gate conductive layer is composed of two parts: the original gate conductive layer 104 serves as the first part and the conductive spacers 130 serve as the second part. Therefore, the gate dielectric layer 102 is formed between the substrate 100 and the first part 104. More important, the base portion 142 of the ONO structure 140 is formed between gate conductive layer composed of the first part 104 and the second part 130 while the body portion 144 of the ONO structure 140 is formed between the first part 104 and the second part 130. In the same concept, the insulating spacers 150 are respectively formed at outside of the second parts 130.

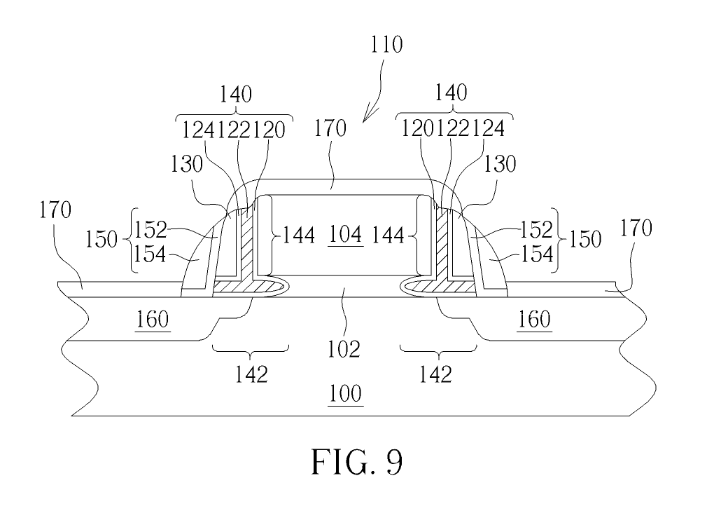

Please refer to FIG. 9, which is a schematic drawing illustrating a modification to the preferred embodiment. According to the modification, a recess is formed on top surface of the body portion 144. Accordingly, the salicide layer 170 electrically connecting the first part 104 and the second part 130 of the gate conductive layer is formed more smoothly and thus electric connection between the first part 104 and the second part 130 is ensured.

According to the non-volatile memory structure and manufacturing method provided by the present invention, the conductive spacers are respectively formed on sidewalls of the gate electrode. The conductive spacers are provided to gain a longer ONO film by constructing the ONO structure. As mentioned above, the length of the charge trapping layer is not only determined by the depth of the cavity and the thickness of the SiN layer, but also by the thickness of the conductive spacer. Therefore the length of the charge trapping layer is increased. Consequently, more charges are stored. Furthermore, since there is no extra photolithography process required, the method for manufacturing the non-volatile memory structure creates the longer ONO film for improving electrical performance without increasing process cost.

Those skilled in the art will readily observe that numerous modifications and alterations of the device and method may be made while retaining the teachings of the invention. Accordingly, the above disclosure should be construed as limited only by the metes and bounds of the appended claims.

1. A non-volatile memory structure, comprising:
a substrate;
a gate electrode formed on the substrate, the gate electrode comprising a gate conductive layer and a gate dielectric layer;
conductive spacers respectively formed on two sides of the gate electrode; and
an oxide-nitride-oxide (ONO) structure having an inverted T shape formed on the substrate, the ONO structure comprising:
a base portion sandwiched between the gate electrode and the substrate, and between the conductive spacer and the substrate; and
a body portion upwardly extended from the base portion, the body portion being sandwiched between the gate electrode and the conductive spacer.

2. The non-volatile memory structure according to claim 1, wherein the gate electrode and the conductive spacers are electrically connected.

3. The non-volatile memory structure according to claim 2, further comprising a salicide layer formed on the gate electrode and the conductive spacers for electrically connecting the gate electrode and the conductive spacers.

4. The non-volatile memory structure according to claim 1, further comprising an insulating spacer respectively formed at outside of the conductive spacers.

5. The non-volatile memory structure according to claim 1, wherein the conductive spacer comprises a width, and the width is between 200 angstroms (A) and 600 Å.

6. The non-volatile memory structure according to claim 1, wherein the base portion of the ONO structure comprises a length, and the length is between 400 Å and 700 Å.

7. A non-volatile memory structure, comprising:
a substrate;
a gate conductive layer formed on the substrate, the gate conductive layer comprising a first part and second parts formed at two sides of the first part;
a gate dielectric layer formed between the substrate and the first part of the gate conductive layer; and
an ONO structure comprising a base portion formed between the gate conductive layer and the substrate and a body portion formed between the first part and the second part of the gate conductive layer.

8. The non-volatile memory structure according to claim 7, further comprising a salicide layer formed on the first part and the second parts of the gate conductive layer.

9. The non-volatile memory structure according to claim 7, further comprising an insulating spacer respectively formed at outside of the second parts of the gate conductive layer.

10. The non-volatile memory structure according to claim 7, wherein the second part of the gate conductive layer comprises a width, and the width is between 200 Å and 600 Å.

11. The non-volatile memory structure according to claim 7, wherein the base portion of the ONO structure comprises a length, and the length is between 400 Å and 700 Å.

12. A method for manufacturing a non-volatile memory structure, comprising:
providing a substrate having a gate electrode formed thereon, the gate electrode comprising a gate conductive layer and a gate dielectric layer;
performing an etch process to remove a portion of the gate dielectric layer to form a cavity under the gate conductive layer;
forming a first silicon oxide layer covering sidewalls of the cavity and a surface of the substrate;
forming a silicon nitride layer on the substrate, the silicon nitride layer filling in the cavity and covering the gate structure;
forming a second silicon oxide layer covering the silicon nitride layer;
forming a conductive layer covering the second silicon oxide layer; and
performing an etching back process to form a conductive spacer respectively at sidewalls of the gate electrode and to form a T-shaped ONO structure.

13. The method for manufacturing the non-volatile memory structure according to claim 12, wherein the cavity comprises a depth, and the depth is between 200 Å and 300 Å.

14. The method for manufacturing the non-volatile memory structure according to claim 12, wherein the conductive layer comprises a thickness, and the thickness is between 200 Å and 600 Å.

15. The method for manufacturing the non-volatile memory structure according to claim 12, further comprising forming an insulating spacer respectively at outside of the conductive spacers after forming the conductive spacers.

16. The method for manufacturing the non-volatile memory structure according to claim 13, further comprising forming a source/drain in the substrate after forming the insulating spacers.

17. The method for manufacturing the non-volatile memory structure according to claim 12, further comprising forming a salicide layer on the gate electrode and the conductive spacers.

18. The method for manufacturing the non-volatile memory structure according to claim 17, wherein the gate electrode and the conductive spacers are electrically connected by the salicide layer.
